(19) United States
(12) Patent Application Publication
(10) Pub. No.: US 2016/0071749 A1
(43) Pub. Date: Mar. 10, 2016

(54) UPPER DOME FOR EPI CHAMBER

(71) Applicant: Applied Materials, Inc., Santa Clara, CA (US)

(72) Inventors: Shu-Kwan LAU, Sunnyvale, CA (US); Mehmet Tugrul SAMIR, Mountain View, CA (US); Anzhong CHANG, San Jose, CA (US)

(21) Appl. No.: 14/826,310

(22) Filed: Aug. 14, 2015

Related U.S. Application Data
(60) Provisional application No. 62/046,414, filed on Sep. 5, 2014.

(51) Int. Cl. H01L 21/67; F27D 1/02

(52) U.S. Cl. CPC H01L 21/67098; F27D 1/025

(57) ABSTRACT

Embodiments described herein relate to a dome assembly. The dome assembly includes an upper dome comprising a convex arc central window, and an upper peripheral flange engaging the central window at a circumference of the central window.

### CROSS-REFERENCE TO RELATED APPLICATIONS

This application claims priority to United States Provisional Patent Application Ser. No. 62/046,414 (Attorney Docket No. 022330/USAL), filed Sep. 5, 2015, which is incorporated by reference herein.

### BACKGROUND

1. Field

Embodiments of the present disclosure generally relate to an upper dome for use in semiconductor processing equipment.

2. Description of the Related Art

Semiconductor substrates are processed for a wide variety of applications, including the fabrication of integrated devices and microdevices. One method of processing substrates includes depositing a material, such as a dielectric material or a conductive metal, on an upper surface of the substrate. For example, epitaxy is a deposition process that grows a thin, ultra-pure layer, usually of silicon or germanium on a surface of a substrate. The material may be deposited in a lateral flow chamber by flowing a process gas parallel to the surface of a substrate positioned on a support, and thermally decomposing the process gas to deposit a material from the gas onto the substrate surface.

Besides substrate and process conditions, however, the reactor design is essential for film quality in epitaxial growth which uses a combination of precision gas flow and accurate temperature control. Flow control, chamber volume, and chamber heating rely on the design of the upper and lower domes which influence epitaxial deposition uniformity. The prior upper dome design restricts process uniformity with sudden large changes in cross sectional area above the substrate which negatively influences flow uniformity, induces turbulence, and affect overall uniformity of deposition gas concentration over the substrate. Similarly, the prior lower dome design restricts process uniformity with sudden large changes in cross sectional area under the substrate which negatively influences temperature uniformity and moves the lamp head far away from the substrate, resulting in poor overall thermal uniformity and minimal zonal control. This in turn limits process uniformity and overall chamber process tenability.

As such, there is a need for a deposition apparatus which provides a uniform thermal field across the substrate.

### SUMMARY

Embodiments described herein relate to a dome assembly for use in a semiconductor processing chamber. The dome assembly includes an upper dome comprising a central window, and a peripheral flange engaging the central window and connecting with an outer circumference of the central window, wherein the central window is convex with respect to the substrate support, and the peripheral flange is at an angle of about 10° to about 30° with respect to a plane defined by a planar upper surface of the peripheral flange.

In one embodiment, an upper dome can include a convex central window portion having a width; a window curvature, the window curvature defined by the ratio of the radius of curvature to the width being at least 10:1; and a peripheral flange having a planar upper surface; a planar lower surface; and an angled flange surface, the peripheral flange engaging the central window portion at a circumference of the central window portion, the angled flange surface having a first surface with a first angle that is less than 35 degrees as measured from the planar upper surface.

In another embodiment, a dome assembly for use in a thermal processing chamber can include an upper dome comprising a horizontal surface; a central window portion having a width and a window curvature, the window curvature defined by a ratio of the radius of curvature to the width, the ratio being at least 10:1; and a peripheral flange having an angled flange surface, the peripheral flange engaging the central window portion at a circumference of the central window portion, the angled flange surface having a first surface at a first angle which is less than 35 degrees as measured from the horizontal surface; and a lower dome opposite the upper dome, the lower dome and the upper dome defining an internal region.

In another embodiment, an upper dome can include a horizontal plane; a central window portion having a window curvature, the window curvature defined by the ratio of the radius of curvature to the width being at least 50:1; and a planar boundary at the circumference; and a peripheral flange having a planar horizontal upper surface; a planar horizontal lower surface; and an angled flange surface with a first surface with a first angle less than 35 degrees as measured from the planar horizontal upper surface; and a second surface between the circumference of the central window portion and the first surface, the second surface having a second angle which is less than 15 degrees as measured from the planar horizontal upper surface, wherein the peripheral flange engages the central window portion at a circumference of the central window portion

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic sectional view of a backside heating process chamber having a liner assembly, according to one embodiment.

FIG. 2A depicts a schematic diagram of an upper dome in accordance with some embodiments.

FIG. 2B is a side view of an upper dome, according to some embodiments.

FIG. 2C depicts a close up view of the connection between the peripheral flange and the central window portion 206, according to one embodiment.

To facilitate understanding, identical reference numerals have been used, wherever possible, to designate identical elements that are common to the Figures. Additionally, elements of one embodiment may be advantageously adapted for utilization in other embodiments described herein.

### DETAILED DESCRIPTION

Embodiments disclosed herein describe a dome assembly including a convex upper dome for use in semiconductor process systems. The upper dome has a central window, and a peripheral flange engaging the central window and connecting with an outer circumference of the central window, wherein the central window is convex with respect to the substrate support, and the peripheral flange is at an angle of about 10° to about 30° with respect to a plane defined by a upper surface of the peripheral flange. The central window is curved toward the substrate which both acts to reduce the processing volume and allow for quick heating and cooling of the substrate during thermal processing. The peripheral flange has multiple curvatures which allow for thermal expansion of the central window without cracking or breaking. Embodiments disclosed herein are more clearly described with reference to the figures below.

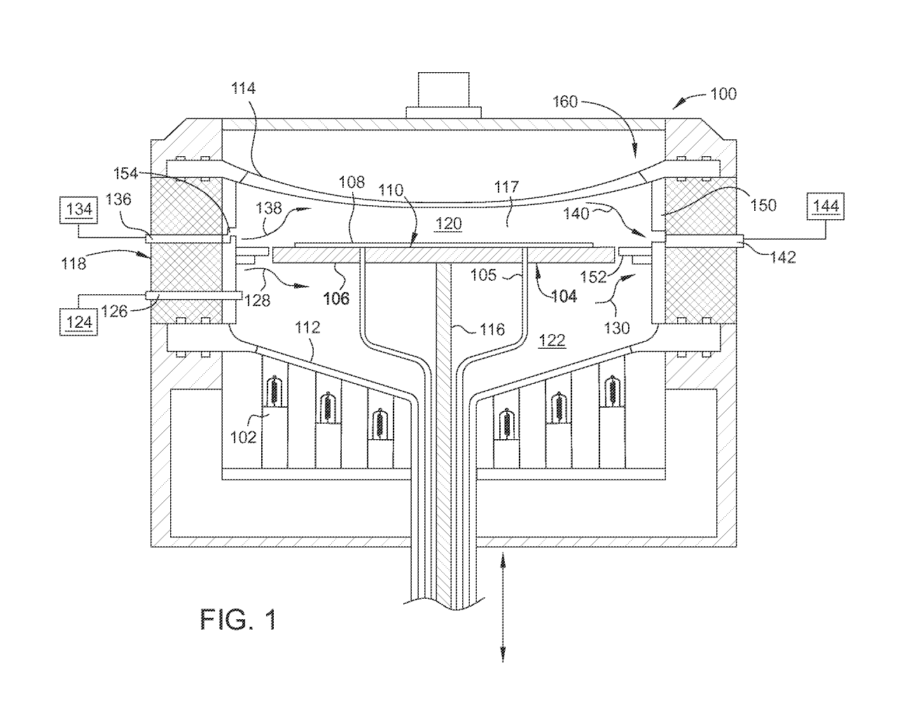

FIG. 1 illustrates a schematic sectional view of a backside heating process chamber 100 with a dome assembly 160, according to one embodiment. One example of the process chamber that may be adapted to benefit from the embodiments described herein is an Epi process chamber, which is available from Applied Materials, Inc., located in Santa Clara, Calif. It is contemplated that other processing chambers, including those from other manufacturers, may be adapted to practice the present embodiments.

The process chamber 100 may be used to process one or more substrates, including the deposition of a material on an upper surface of a substrate 108. The process chamber 100 can include a process chamber heating device, such as an array of radiant heating lamps 102 for heating, among other components, a back side 104 of a substrate support 106 or the back side of the substrate 108 disposed within the process chamber 100. The substrate support 106 may be a disk-like substrate support 106 as shown, or may be a ring-like substrate support (not shown), which supports the substrate from the edge of the substrate or may be a pin-type support which supports the substrate from the bottom by minimal contact posts or pins.

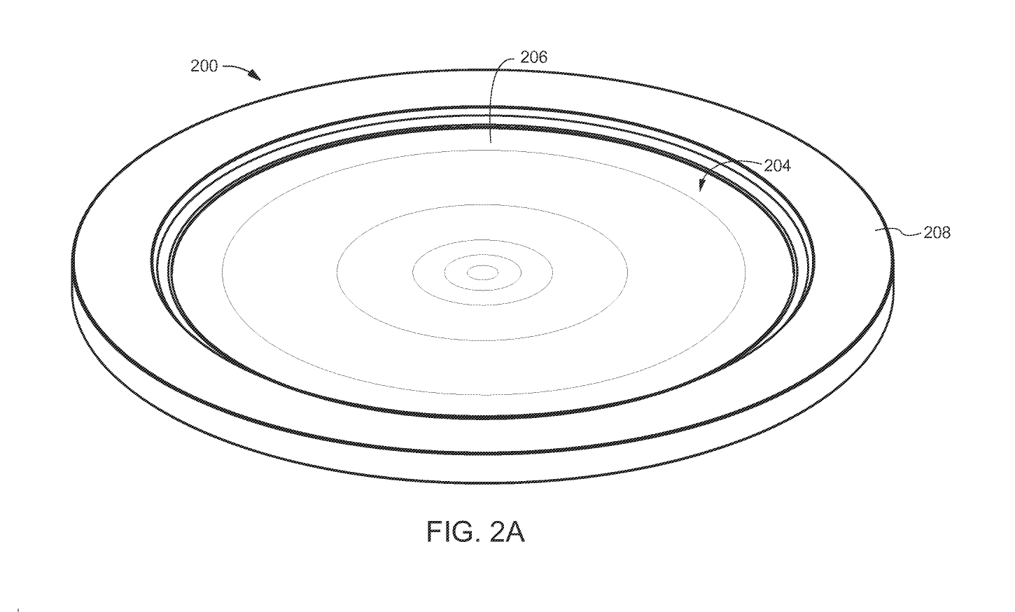

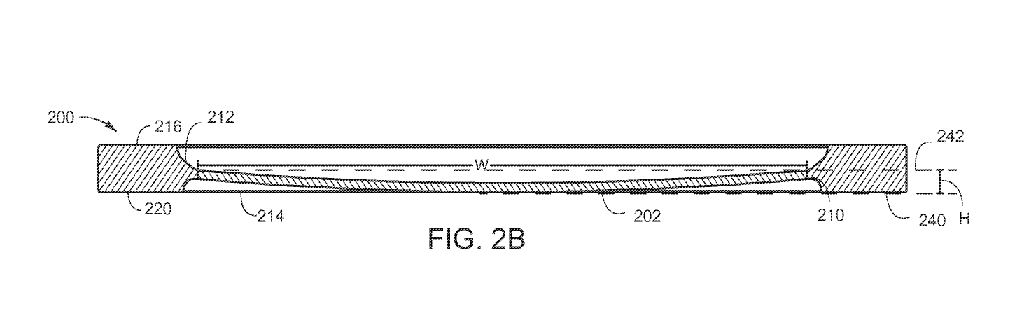

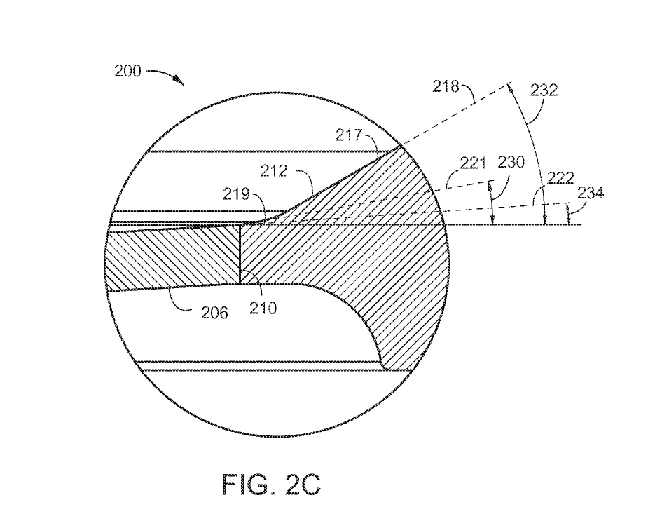

In this embodiment, the substrate support 106 is depicted as located within the process chamber 100 between an upper dome 114 and a lower dome 112. A dome assembly 160 includes an upper dome 114 and a lower dome 112. The upper dome 114 and the lower dome 112, along with a base ring 118 that is disposed between the upper dome 114 and lower dome 112, define an internal region of the process chamber 100. The substrate 108 can be brought into the process chamber 100 and positioned onto the substrate support 106 through a loading port, which is not visible in FIG. 1. The upper dome 114 is discussed in more detail with reference to FIGS. 2A-2C.

The base ring 118 can generally include the loading port, a process gas inlet 136, and a gas outlet 142. The base ring 118 may have any desired shape as long as the loading port 103, the process gas inlet 136 and the gas outlet 142 are angularly offset at about 90 degrees with respect to each other and the loading port. For example, the loading port 103 may be located at a side between the process gas inlet 136 and the gas outlet 142, with the process gas inlet 136 and the gas outlet 142 disposed at opposing ends of the base ring 118. In various embodiments, the loading port, the process gas inlet 136 and the gas outlet 142 are aligned to each other and disposed at substantially the same level.

The substrate support 106 is shown in an elevated processing position, but may be vertically traversed by an actuator (not shown) to a loading position below the processing position to allow lift pins 105 to contact the lower dome 112, passing through holes in the substrate support 106 and a central shaft 116, and raise the substrate 108 from the substrate support 106. A robot (not shown) may then enter the process chamber 100 to engage and remove the substrate 108 therefrom though the loading port. The substrate support 106 then may be actuated up to the processing position to place the substrate 108, with its device side 117 facing up, on a front side 110 of the substrate support 106.

The substrate support 106, while located in the processing position, divides the internal volume of the process chamber 100 into a processing region 120 that is above the substrate, and a purge gas region 122 below the substrate support 106. The substrate support 106 can be rotated during processing by the central shaft 116 to minimize the effect of thermal and process gas flow spatial anomalies within the process chamber 100 and thus facilitate uniform processing of the substrate 108. The substrate support 106 is supported by the central shaft 116, which moves the substrate 108 in an up and down direction during loading and unloading, and in some instances, processing of the substrate 108. The substrate support 106 may be formed from silicon carbide or graphite coated with silicon carbide to absorb radiant energy from the lamps 102 and conduct the radiant energy to the substrate 108.

In general, the central window portion of the upper dome 114 and the bottom of the lower dome 112 are formed from an optically transparent material, such as quartz. The thickness and the degree of curvature of the upper dome 114 may be configured to manipulate the uniformity of the flow field in the process chamber. The upper dome 114 is described in more detail with reference to FIGS. 2A and 2B.

The lamps 102 can be disposed adjacent to and beneath the lower dome 112 in a specified manner around the central shaft 116 to independently control the temperature at various regions of the substrate 108 as the process gas passes over, thereby facilitating the deposition of a material onto the upper surface of the substrate 108. The lamps 102 may configured to heat the substrate 108 to a temperature within a range of about 200 degrees Celsius to about 1600 degrees Celsius. While not discussed here in detail, the deposited material may include silicon, doped silicon, germanium, doped germanium, silicon germanium, doped silicon germanium, gallium arsenide, gallium nitride, or aluminum gallium nitride.

Process gas supplied from a process gas supply source 134 is introduced into the processing region 120 through a process gas inlet 136 formed in the sidewall of the base ring 118. The process gas inlet 136 connects to the process gas region through a plurality of gas passages 154 formed through the liner assembly 150. The process gas inlet 136, the liner assembly 150, or combinations thereof, are configured to direct the process gas in a direction which can be generally radially inward. During the film formation process, the substrate support 106 is located in the processing position, which can be adjacent to and at about the same elevation as the process gas inlet 136, allowing the process gas to flow up and round along flow path 138 across the upper surface of the substrate 108. The process gas exits the processing region 120 (along the flow path 140) through a gas outlet 142 located on the opposite side of the process chamber 100 as the process gas inlet 136. Removal of the process gas through the gas outlet 142 may be facilitated by a vacuum pump 144 coupled thereto.

Purge gas supplied from a purge gas source 124 is introduced to the purge gas region 122 through a purge gas inlet 126 formed in the sidewall of the base ring 118. The purge gas inlet 126 connects to the process gas region through the liner assembly 150. The purge gas inlet 126 is disposed at an elevation below the process gas inlet 136. If the circular shield 152 is used, the circular shield 152 may be disposed between the process gas inlet 136 and the purge gas inlet 126. In either case, the purge gas inlet 126 is configured to direct the purge gas in a generally radially inward direction. If desired, the purge gas inlet 126 may be configured to direct the purge gas in an upward direction.

During the film formation process, the substrate support 106 is located at a position such that the purge gas flows down and round along flow path 128 across back side 104 of the substrate support 106. Without being bound by any particular theory, the flowing of the purge gas is believed to prevent or substantially avoid the flow of the process gas from entering into the purge gas region 122, or to reduce diffusion of the process gas entering the purge gas region 122 (i.e., the region under the substrate support 106). The purge gas exits the purge gas region 122 (along flow path 130) and is exhausted out of the process chamber through the gas outlet 142 located on the opposite side of the process chamber 100 as the purge gas inlet 126.

FIGS. 2A and 2B are schematic illustrations of an upper dome 200 that may be used in a thermal process chamber according to embodiments described herein. FIG. 2A illustrates a top perspective view of the upper dome 200. FIG. 2B illustrates a cross-section of the upper dome 200. The upper dome 200 has a substantially circular shape (FIG. 2A) and has a slightly concave outside surface 202 and a slightly convex inside surface 204 (FIG. 2B). As will be discussed in more detail below, the concave outside surface 202 is sufficiently curved to oppose the compressive force of the exterior atmosphere pressure against the reduced internal pressure in the process chamber during substrate processing, while flat enough to promote the orderly flow of the process gas and the uniform deposition of the reactant material.

The upper dome 200 generally includes a central window portion 206 which is substantially transparent to infrared radiations, and a peripheral flange 208 for supporting the central window portion 206. The central window portion 206 is shown as having a generally circular periphery. The peripheral flange 208 engages the central window portion 206 at and around a circumference of the central window portion 206 along a support interface 210. The central window portion 206 may have a convex curvature with relation to a horizontal plane 214 of the peripheral flange.

The central window portion 206 of the upper dome 200 may be formed from a material, such as clear quartz, that is generally optically transparent to the direct radiations from the lamps without significant absorption of desired wavelengths of radiation. Alternatively, the central window portion 206 may be formed from a material having narrow band filtering capability. Some of the heat radiation re-radiated from the heated substrate and the substrate support may pass into the central window portion 206 with significant absorption by the central window portion 206. These re-radiations generate heat within the central window portion 206, producing thermal expansion forces.

The central window portion 206 is shown here as being circular in the length and width directions, with a circumference forming the boundary between the central window portion 206 and the peripheral flange 208. However, the central window portion may have other shapes as desired by the user.

The peripheral flange 208 may be made from an opaque quartz or other opaque material. The peripheral flange 208, which may be made opaque, remains relatively cooler than the central window portion 206, thereby causing the central window portion 206 to bow outward beyond the initial room temperature bow. As a result, the thermal expansion within the central window portion 206 is expressed as thermal compensation bowing. The thermal compensation bowing of the central window portion 206 increases as the temperature of the process chamber increases. The central window portion 206 is made thin and has sufficient flexibility to accommodate the bowing, while the peripheral flange 208 is thick and has sufficient rigidness to confine the central window portion 206.

In one embodiment, the upper dome 200 is constructed in a manner that the central window portion 206 is an arc with a ratio of the radius of curvature to the width “W” of the central window portion 206 which is at least 5:1. In one example, the radius of curvature to the width “W” is greater than 10:1, such as between about 10:1 and about 50:1. In another embodiment, the radius of curvature to the width “W” is greater than 50:1, such as between about 50:1 and about 100:1. The width “W” is the width of the central window portion 206 between the boundaries set by the peripheral flange 208 as measured through the center of the central window portion 206. Greater or less in the context of the above ratio refers to increasing or decreasing the value of the antecedent (i.e., the radius of curvature) proportionally to the consequent (i.e., the width “W”).

In another embodiment shown in FIG. 2B, the upper dome 200 is constructed in a manner that the central window portion 206 is an arc with a ratio of the width “W” to the height “H” of the central window portion 206 which is at least 5:1. In one example, the ratio of the width “W” to the height “H” is greater than 10:1, such as between about 10:1 and about 50:1. In another embodiment, the ratio of the width “W” to the height “H” is greater than 50:1, such as between about 50:1 and about 100:1. The height “H” is the height of the central window portion 206 between the boundaries set by a first boundary line 240 and a second boundary line 242. The first boundary line 240 is tangent to the peak point of the portion of the curve in the central window portion 206 facing the processing region 120. The second boundary line 242 intersects the points of the support interface 210 furthest from the processing region 120.

The upper dome 200 may have a total outer diameter of about 200 mm to about 500 mm, such as about 240 mm to about 330 mm, for example about 295 mm. The central window portion 206 may have a constant thickness of about 2 mm to about 10 mm, for example about 2 mm to about 4 mm, about 4 mm to about 6 mm, about 6 mm to about 8 mm, about 8 mm to about 10 mm. In some examples, the central window portion 206 is about 3.5 mm to about 6.0 mm in thickness. In one example, the central window portion 206 is about 4 mm in thickness.

The thinner central window portion 206 provides a smaller thermal mass, enabling the upper dome 200 to heat and cool rapidly. The central window portion 206 may have an outer diameter of about 130 mm to about 250 mm, for example about 160 mm to about 210 mm. In one example, the central window portion 206 is about 190 mm in diameter.

The peripheral flange 208 may have a thickness of about 25 mm to about 125 mm, for example about 45 mm to about 90 mm. The thickness of the peripheral flange 208 is generally defined as a thickness between the planar upper surface 216 and the planar bottom surface 220. In one example, the peripheral flange 208 is about 70 mm in thickness. The peripheral flange 208 may have a width of about 5 mm to about 90 mm, for example about 12 mm to about 60 mm, which may vary with radius. In one example, the peripheral flange 208 is about 30 mm in width. If the liner assembly is not used in the process chamber, the width of the peripheral flange 208 may be increased by about 50 mm to about 60 mm and the width of the central window portion 206 is decreased by the same amount.

The central window portion 206 has a thickness between 5 mm and 8 mm, such as a 6 mm thickness. The thickness of the central window portion 206 of the upper dome 200 is selected at a range as discussed above to ensure that shear stresses developed at the interface between the peripheral flange 208 and the central window portion 206 is addressed. In one embodiment, the thinner quartz wall (i.e., the central window portion 206) is a more efficient heat transfer medium so that less energy is absorbed by the quartz. The upper dome therefore remains relatively cooler. The thinner wall domes will also stabilize in temperature faster and respond to convective cooling quicker since less energy is being stored and the conductive path to the outside surface is shorter. Therefore, the temperature of the upper dome 200 can be more closely held at a desired set point to provide better thermal uniformity across the central window portion 206. In addition, while the central window portion 206 conducts radially to the peripheral flange 208, a thinner dome wall results in improved temperature uniformity over the substrate. It is also advantageous to not excessively cool the central window portion 206 in the radial direction as this would result in unwanted temperature gradients which will reflect onto the surface of the substrate being processed and cause film uniformity to suffer.

FIG. 2C depicts a close up view of the connection between the peripheral flange 208 and the central window portion 206, according to one embodiment. The peripheral flange 208 has an angled flange surface 212 which has at least a first surface 217, indicated by a surface line 218. The first surface 217 is at an angle of about 20° to about 30° with respect to a plane defined by the planar upper surface 216 of the peripheral flange 208. The angle of the first surface 217 may be defined with the planar upper surface 216 or the horizontal plane 214. The planar upper surface 216 is horizontal. The horizontal plane 214 is parallel to the planar upper surface 216 of the peripheral flange 208.

The first angle 232 can be more specifically defined as the angle between the planar upper surface 216 of the peripheral flange 208 (or the horizontal plane 214) and a surface line 218 on the convex inside surface 204 of the central window portion 206 that passes through an intersection of the central window portion 206 and the peripheral flange 208. In various embodiments, the first angle 232 between the horizontal plane 214 and the surface line 218 is generally less than 35°. In one embodiment, the first angle 232 is about 6° to about 20°, such as between about 6° and about 8°, about 8° and about 10°, about 10° and about 12°, about 12° and about 14°, about 14° and about 16°, about 16° and about 18°, about 18° and about 20°. In one example, the first angle 232 is about 10°. In another example, the first angle 232 is about 30°. The angled flange surface 212 with the first angle 232 at about 20° provides structural support to the central window portion 206 as supported by the peripheral flange 208.

In another embodiment, the angled flange surface 212 can have one or more additional angles, depicted here as a second angle 230 formed from a second surface 219, as depicted by a surface line 221. The second angle 230 of the angled flange surface 212 is an angle between a support angle 234 of the peripheral flange 208 and the first angle 232. The support angle 234 is the angle between the tangent surface 222, which is formed from the convex inside surface 204 at the support interface 210, and the horizontal plane 214. For example, if the support angle 234 is 3° and the first angle 232 is 30°, the second angle 230 is between 3° and 30°. The second angle 230 provides additional stress reduction by redirecting the forces with two sequential redirections, rather than a single redirection which further disperses the forces created by expansion and pressure.

The support angle 234, the first angle 232 and the second angle 230 may have angles which create a fluid transition between end surfaces between the first surface 217, the second surface 219 and the tangent surface 222. In one example, the tangent surface 222 has an end surface which has a fluid transition with an end surface of the second surface 219. In another example, the second surface 219 has an end surface which has a fluid transition with an end surface of the first surface 217. An end surface, as used herein, is formed at an imaginary separation between any of the first surface 217, the second surface 219 or the tangent surface 222. A fluid transition between end surfaces is a transition between surfaces which connects without forming visible edges.

It is believed that the angle of the angled flange surface 212 allows for thermal expansion of the upper dome 200 while reducing the processing volume in the processing region 120. Without intending to be bound by theory, scaling of existing upper domes for thermal processing will increase the processing volume, thus wasting reactant gases, decreasing throughput, decreasing deposition uniformity and increasing costs. The angled flange surface 212 allows for expansion stresses to be absorbed without changing the ratio described above. By adding the angled flange surface 212, the antecedent of the ratio of the radius of curvature to the width of the central window portion 206 can be increased. By increasing the antecedent of the ratio, the curvature of the central window portion 206 becomes more flat allowing for a smaller chamber volume.

Embodiments of an upper dome are disclosed herein. The upper dome includes at least a convex central window and a peripheral flange having a plurality of angles. The convex central window reduces the space in the processing region and the substrate can be more efficiently heated and cooled during thermal processing. The peripheral flange has a plurality of angles formed in conjunction with the central window and away from the processing region. The plurality of angles provide stress relief to the central window during the heating and cooling steps. Further, the angles of the peripheral flange allow for a thinner flange and a thinner central window to further reduce process volume. By reducing process volume and component size, production and processing costs can be reduced without compromising quality in the end product or life cycle of the dome assembly.

While the foregoing is directed to embodiments of the disclosed devices, methods and systems, other and further embodiments of the disclosed devices, methods and systems may be devised without departing from the basic scope thereof, and the scope thereof is determined by the claims that follow.

1. An upper dome comprising:
a convex central window portion having:
a height;
a width; and
a window curvature defined by the ratio of the width to the height being at least 10:1;
and
a peripheral flange having:
a planar upper surface;
a planar lower surface; and
an angled flange surface, the peripheral flange engaging the central window portion at a circumference of the central window portion, the angled flange surface having a first surface with a first angle that is less than 35 degrees as measured from the planar upper surface.

2. The upper dome of claim 1, wherein the angled flange surface further comprises a second surface which is formed between the circumference of the central window portion and the first surface, the second surface having a second angle.

3. The upper dome of claim 2, wherein the second angle is less than 15 degrees as measured from the planar upper surface.

4. The upper dome of claim 2, wherein the central window portion has a tangent surface with support angle, the support angle being less than 10 degrees.

5. The upper dome of claim 4, wherein the tangent surface has an end surface that has a fluid transition with an end surface of the second surface, and wherein the second surface has an end surface which has a fluid transition with an end surface of the first surface.

6. The upper dome of claim 5, wherein the support angle is less than the second angle and the second angle is less than the first angle.

7. The upper dome of claim 1, wherein the window curvature is defined by the ratio of a radius of curvature to the width being at least 10:1.

8. The upper dome of claim 1, wherein the ratio of the radius of curvature to the width is greater than 50:1

9. The upper dome of claim 2, wherein the ratio of the size of the first angle to the size of the second angle is about 3:1.

10. A dome assembly for use in a thermal processing chamber, comprising:
an upper dome comprising:
a horizontal surface;
a central window portion having a height, a width and a window curvature, the window curvature defined by a ratio of the width to the height, the ratio being at least 10:1; and
a peripheral flange having an angled flange surface, the peripheral flange engaging the central window portion at a circumference of the central window portion, the angled flange surface having a first surface at a first angle which is less than 35 degrees as measured from the horizontal surface; and
a lower dome opposite the upper dome, the lower dome and the upper dome defining an internal region.

11. The dome assembly of claim 10, wherein the angled flange surface further comprises a second surface between the circumference of the central window portion and the first surface, the second surface having a second angle.

12. The dome assembly of claim 11, wherein the second angle is less than 15 degrees as measured from the horizontal surface.

13. The dome assembly of claim 11, wherein the central window portion has a circumference which forms a tangent surface, the tangent surface having a support angle, the support angle being less than 10 degrees.

14. The dome assembly of claim 13, wherein the tangent surface has an end point which is collinear with an end point of the second surface, and wherein the second surface has an end point which is collinear with an end point of the first surface.

15. The dome assembly of claim 14, wherein the support angle is less than the second angle which is less than the first angle.

16. The dome assembly of claim 10, wherein the peripheral flange has a thickness of less than 50 mm.

17. The upper dome of claim 10, wherein the ratio of the radius of curvature to the width is between about 50:1 and about 100:1.

18. The upper dome of claim 11, wherein the ratio of the size of the first angle to the size of the second angle is about 3:1.

19. An upper dome comprising:
a horizontal plane;
a central window portion having:
a window curvature, the window curvature defined by the ratio of the width to the height being at least 50:1;
and
a planar boundary at the circumference; and
a peripheral flange having:
a planar horizontal upper surface;
a planar horizontal lower surface; and
an angled flange surface with
a first surface with a first angle less than 35 degrees as measured from the planar horizontal upper surface; and
a second surface between the circumference of the central window portion and the first surface, the second surface having a second angle which is less than 15 degrees as measured from the planar horizontal upper surface,
wherein the peripheral flange engages the central window portion at a circumference of the central window portion.

20. The upper dome of claim 19, wherein a ratio of the size of the first angle to the size of the second angle is about 3:1.
